(19) United States
(12) Patent Application Publication
(10) Pub. No.: US 2025/0154645 A1
(43) Pub. Date: May 15, 2025

(54) FILM FORMING METHOD AND FILM FORMING APPARATUS

(71) Applicant: Tokyo Electron Limited, Minato-ku, Tokyo (JP)

(72) Inventors: Tadashi MITSUNARI, Nirasaki City, Yamanashi (JP); Hiroki ARAI, Nirasaki City, Yamanashi (JP); Yuutaro KISHI, Nirasaki City, Yamanashi (JP); Yasuhiro HAMADA, Nirasaki City, Yamanashi (JP)

(21) Appl. No.: 18/838,661

(22) PCT Filed: Feb. 6, 2023
(86) PCT No.: PCT/JP2023/003733

§ 371 Date: Aug. 15, 2024

(30) Foreign Application Priority Data
Feb. 18, 2022 (JP) 2022-023572

(51) Int. Cl. C23C 16/26; C23C 16/509; H01J 37/32; H01L 21/02

(52) U.S. Cl. CPC C23C 16/26; C23C 16/509; H01J 37/32834; H01L 21/02115; H01L 21/02274; H01J 2237/3321

(57) ABSTRACT

A film forming method includes placing a substrate on a substrate placement stage provided inside a processing container, exhausting and depressurizing an inside of the processing container, forming a carbon film on the substrate by generating plasma through application of radio frequency power for plasma generation to the substrate placement stage while supplying a process gas including a carbon-containing gas into the depressurized processing container, and performing plasma processing by applying a negative direct current voltage to a counter electrode facing the substrate placement stage, along with application of the radio frequency power for plasma generation to the substrate placement stage.

### TECHNICAL FIELD

The present disclosure relates to a film forming method and a film forming apparatus.

### BACKGROUND

Patent Document 1 discloses a method of depositing an amorphous carbon layer for a hard mask. In the method, an RF power supply and a matching circuit network are coupled to a shower head or to both sides of the shower head and a wafer pedestal, and an electric field is generated between the shower head and the wafer pedestal to form plasma. Thus, plasma pyrolysis of a hydrocarbon compound is generated, thereby depositing the amorphous carbon layer.

### PRIOR ART DOCUMENTS

### Patent Documents

Patent Document: Japanese Patent Laid-Open Publication No. 2002-12972

The present disclosure provides some embodiments of a film forming method and a film forming apparatus capable of forming a carbon layer with low stress.

### SUMMARY

According to one embodiment of the present disclosure, a film forming method includes placing a substrate on a substrate placement stage provided inside a processing container, exhausting and depressurizing an inside of the processing container, forming a carbon film on the substrate by generating plasma through application of radio frequency power for plasma generation to the substrate placement stage while supplying a process gas including a carbon-containing gas into the depressurized processing container, and performing plasma processing by applying a negative direct current voltage to a counter electrode facing the substrate placement stage, along with application of the radio frequency power for plasma generation to the substrate placement stage.

According to the present disclosure, it is possible to provide a film forming method and a film forming apparatus capable of forming a carbon film with low stress.

### BRIEF DESCRIPTION OF DRAWINGS

FIG. 1 is a cross-sectional view schematically illustrating an example of a film forming apparatus for performing a film forming method according to a first embodiment.

FIG. 2 is a flowchart illustrating an exemplary flow of the film forming method according to the first embodiment.

FIG. 3 is a cross-sectional view illustrating an exemplary structure of a substrate used in the film forming method according to the first embodiment.

FIG. 4 is a cross-sectional view illustrating a state in which a carbon film is formed on the substrate in FIG. 3.

FIG. 5 is a diagram schematically illustrating a state when a carbon film is formed through plasma CVD by converting a carbon-containing gas into plasma in step ST3.

FIG. 6 is a diagram schematically illustrating a state when a negative direct current voltage is applied to an upper electrode in the state of FIG. 5.

FIG. 7 is a diagram schematically illustrating a state in which carbon particles sputtered and emitted from a carbon film of an upper electrode are implanted into the carbon film on a substrate by applying a negative direct current voltage to the upper electrode.

FIG. 8 is a diagram illustrating conditions of deposition and direct current (DC) plasma in an experiment for verifying that stress is relieved by implanting carbon particles into a carbon film.

FIG. 9A is a diagram illustrating a relationship between time and a carbon film thickness in step ST4 as a result of the experiment for verifying that stress is relieved by implanting carbon particles into a carbon film.

FIG. 9B is a diagram illustrating a relationship between time and film stress in step ST4 as a result of the experiment for verifying that stress is relieved by implanting carbon particles into the carbon film.

FIG. 10A is a diagram illustrating a relationship between a DC voltage applied to an upper electrode and a carbon film thickness in step ST4 as a result of an experiment for verifying a desirable range of a DC voltage applied to the upper electrode.

FIG. 10B is a diagram illustrating a relationship between a DC voltage applied to an upper electrode and film stress in step ST4 as a result of the experiment for verifying the desirable range of the DC voltage applied to the upper electrode.

FIG. 11 is a diagram illustrating a result of an experiment for verify a desirable range of a film thickness of a carbon film per cycle when a process of forming a carbon film in step ST3 and a process of applying a DC voltage in step ST4 are alternately repeated.

FIG. 12A is a diagram illustrating a relationship between pressure and a carbon film thickness in step ST4 as a result of an experiment for verifying a desirable range of pressure in the process of applying the DC voltage in step ST4.

FIG. 12B is a diagram illustrating a relationship between pressure and film stress in step ST4 as the result of the experiment for verifying a desirable range of pressure in the process of applying the DC voltage in step ST4.

FIG. 13A is a diagram illustrating a relationship between HF power and a carbon film thickness in step ST4 as a result of an experiment for verifying a desirable range of the HF power in the process of applying the DC voltage in step ST4.

FIG. 13B is a diagram illustrating a relationship between HF power and film stress in step ST4 as a result of the experiment for verifying the desirable range of the HF power in the process of applying the DC voltage in step ST4.

FIG. 14 is a cross-sectional view illustrating another example of a film forming apparatus.

FIG. 15 is a flowchart illustrating an exemplary flow of a film forming method according to a second embodiment.

FIG. 16 is a schematic diagram schematically illustrating main parts of another film forming apparatus capable of performing the film forming method according to the second embodiment.

### DETAILED DESCRIPTION

Hereinafter, embodiments will be described with reference to the accompanying drawings.

### First Embodiment

First, a first embodiment will be described.

### [Example of Film Forming Apparatus]

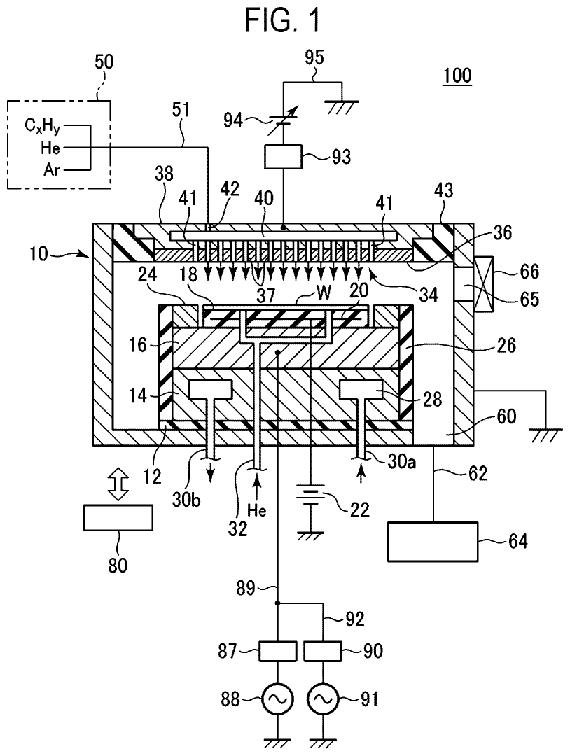

FIG. 1 is a cross-sectional view schematically illustrating an example of a film forming apparatus for performing a film forming method according to a first embodiment.

A film forming apparatus 100 of the present example forms a carbon film suitable for a hard mask on a substrate W and is configured as a capacitively coupled plasma processing apparatus. The substrate W can be, for example, a semiconductor wafer, but is not limited thereto.

The film forming apparatus 100 includes a processing container (chamber) 10 that has an approximately cylindrical shape and is made of metal, for example, aluminum, the surface of which is anodized. The processing container 10 is securely grounded.

A metal support base 14 of a cylindrical shape is arranged at the bottom of the processing container 10 via an insulating plate 12 made of ceramics or the like, and a substrate placement stage 16 made of metal, for example, aluminum, is provided on the support base 14. The substrate placement stage 16 constitutes a lower electrode. The substrate placement stage 16 has, on an upper surface thereof, an electrostatic chuck 18 that attracts and holds the substrate W by electrostatic force. The electrostatic chuck 18 has a structure in which an electrode 20 is provided inside an insulator and attracts and holds the substrate W by electrostatic force such as Coulomb force by applying a direct current (DC) voltage to the electrode 20 from a DC power supply 22 for attraction.

A conductive focus ring 24 made of, for example, silicon, is arranged around the electrostatic chuck 18 to improve the uniformity of plasma processing. An inner wall member 26 of a cylindrical shape made of, for example, quartz, is provided on side surfaces of the substrate placement stage 16 and the support base 14.

A coolant chamber 28 is provided inside the support base 14. A coolant, for example, cooling water, is circulated and supplied to the coolant chamber 28 via pipes 30a and 30b from a chiller unit (not shown) provided outside the coolant chamber 28, and a processing temperature of the substrate W on the substrate placement stage 16 is controlled by the coolant.

Further, a heat transfer gas, for example, He gas, is supplied between an upper surface of the electrostatic chuck 18 and a rear surface of the substrate W via a gas supply line 32 from a heat transfer gas supply which is not shown.

A first radio frequency power supply 88 for generating plasma and a second radio frequency power supply 91 for applying a bias are electrically connected to the substrate placement stage 16 serving as the lower electrode. A matcher 87 is disposed on a feeder 89 that feeds power from the first radio frequency power supply 88 to the substrate placement stage 16. A feeder 92 from the second radio frequency power supply 91 is connected to the feeder 89, and a matcher 90 is disposed on the feeder 92. The first radio frequency power supply 88 has a higher frequency than the second radio frequency power supply 91. A frequency of radio frequency power supplied from the first radio frequency power supply 88 is desirably 40 MHz or higher. A frequency of radio frequency power supplied from the second radio frequency power supply 91 is desirably 3.2 MHz or lower. As an example, a combination of the first radio frequency power supply 88 of 40 MHz and the second radio frequency power supply 91 of 3.2 MHz is desirable. The radio frequency power supplied from the first radio frequency power supply 88 is desirably in a range of 100 W to 1 KW, and the radio frequency power supplied from the second radio frequency power supply 91 is desirably in a range of 500 W to 5 kW.

The matchers 87 and 90 serve to match load (plasma) impedance to impedances of the first and second radio frequency power supplies 88 and 91, respectively. That is, the matchers 87 and 90 function so that internal impedances of the first and second radio frequency power supplies 88 and 91 and the load impedance appear to match when plasma is generated inside the processing container 10.

An upper electrode 34 is provided above the substrate placement stage (lower electrode) 16 so as to face the substrate placement stage 16. A space between the upper electrode 34 and the substrate placement stage (lower electrode) 16 becomes a plasma generation space. A distance between the lower electrode 16 and the upper electrode 34 is in an order of a few centimeters (cm).

The upper electrode 34 is supported on an upper portion of the processing container 10 via an insulating shielding member 43. The upper electrode 34 includes an electrode plate 36 that forms a surface facing the substrate placement stage 16 and has a plurality of gas discharge holes 37, and an electrode support body 38 that detachably supports the electrode plate 36. The electrode plate 36 is made of a conductor, and can be made of, for example, silicon, which is commonly used, but may be made of carbon as described later. A gas diffusion chamber 40 is provided inside the electrode support body 38, and a plurality of gas flow holes 41 that communicates with the gas discharge holes 37 extends downward from the gas diffusion chamber 40. A gas introduction port 42 that introduces a process gas into the gas diffusion chamber 40 is formed in the electrode support body 38, and a gas pipe 51 that is connected to a gas supply 50 described later is connected to the gas introduction port 42. The process gas supplied from the gas supply 50 is supplied to the gas diffusion chamber 40 and is supplied into the processing container 10 via the gas flow holes 41 and the gas discharge holes 37 toward the substrate placement stage 16 serving as the lower electrode. That is, the upper electrode 34 is configured as a shower head.

A DC power supply 94 for applying a negative DC voltage via a feeder 95 is electrically connected to the upper electrode 34. A low-pass filter 93 is connected to the feeder 95 downstream of the DC power supply 94. The low-pass filter 93 serves to prevent radio frequency power from the radio frequency power supplies 88 and 91 from being supplied to the DC power supply 94. An absolute value of a DC voltage from the DC power supply 94 is desirably 300 V or more.

The gas supply 50 has a plurality of gas supply sources for supplying gases such as carbon-containing gas (CₓH_{y}), noble gases such as Ar gas and He gas, and hydrogen gas (H₂ gas), and a plurality of gas supply pipes for supplying respective gases from the plurality of gas supply sources. Each gas supply pipe is provided with an opening/closing valve and a flow rate controller such as a mass flow controller (both not shown), which perform the supply and stop of the above gases and the flow rate control of each gas. In this example, the He gas and the Ar gas are supplied as the noble gases, but the noble gases are not limited thereto and may be, for example, only the Ar gas or other noble gases. Alternatively, the noble gases may be only the carbon-containing gas.

An exhaust port 60 is provided at the bottom of the processing container 10, and an exhauster 64 is connected to the exhaust port 60 via an exhaust pipe 62. The exhauster 64 has an automatic pressure control valve and a vacuum pump, and the inside of the processing container 10 can be exhausted and maintained at a desired vacuum level by the exhauster 64. A loading/unloading port 65 for loading and unloading the substrate W into and from the processing container 10 is provided on a side wall of the processing container 10 and is configured to be opened and closed by a gate valve 66. A detachable deposition shield (not shown) is provided along the inner wall of the processing container 10 to prevent etching-by-products (deposition) from adhering to the processing container 10.

The valve or the flow rate controller of the gas supply 50, the radio frequency power supplies 88 and 91, and the DC power supply 94, which are components of the film forming apparatus 100, are controlled by a controller 80. The controller 80 has a main controller having a CPU, an input device, an output device, a display device, and a storage device. Processing of the film forming apparatus 100 is controlled based on a processing recipe stored in a storage medium of the storage device.

### [Film Forming Method]

Next, a film forming method according to the first embodiment performed by the film forming apparatus of FIG. 1 will be described.

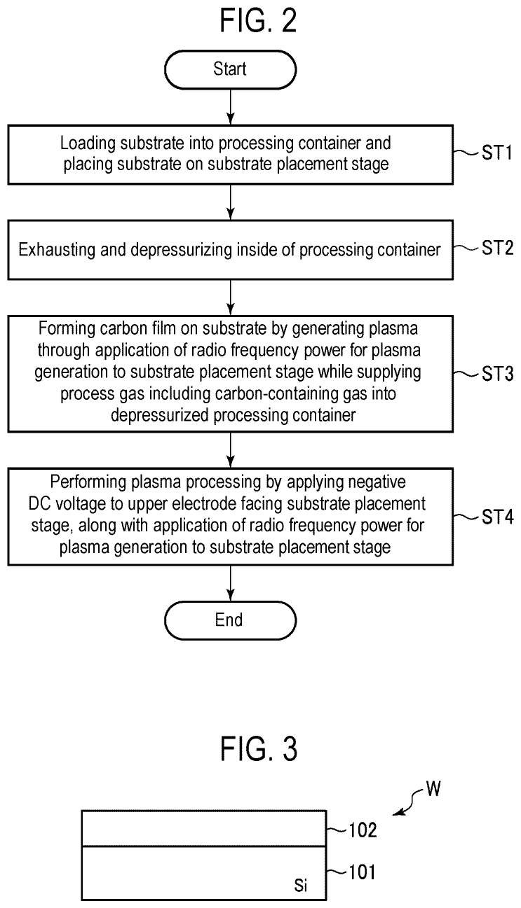

FIG. 2 is a flowchart illustrating an exemplary flow of the film forming method according to the first embodiment.

As shown in FIG. 2, in this embodiment, steps ST1 to ST4 are performed.

In step ST1, the substrate W is loaded into the processing container 10 and placed on the substrate placement stage 16. In this case, the temperature of the substrate placement stage 16 is desirably set such that the temperature of the substrate W placed thereon is 150 degrees C. or lower. For example, a semiconductor wafer can be used as the substrate W. As the semiconductor wafer, which is the substrate W, an example in which a base film 102 is formed on a Si substrate 101 is illustrated as in FIG. 3. As the base film 102, a Si-containing film such as a SiO₂ film (e.g., a thermal oxide film) or a SiNₓ film is exemplified.

In step ST2, the inside of the processing container 10 is exhausted and depressurized. In this case, the inside of the processing container 10 is exhausted while supplying an inert gas, for example, a noble gas such as Ar gas or He gas. The pressure inside the processing container 10 is desirably 20 mTorr (2.66 Pa) or lower.

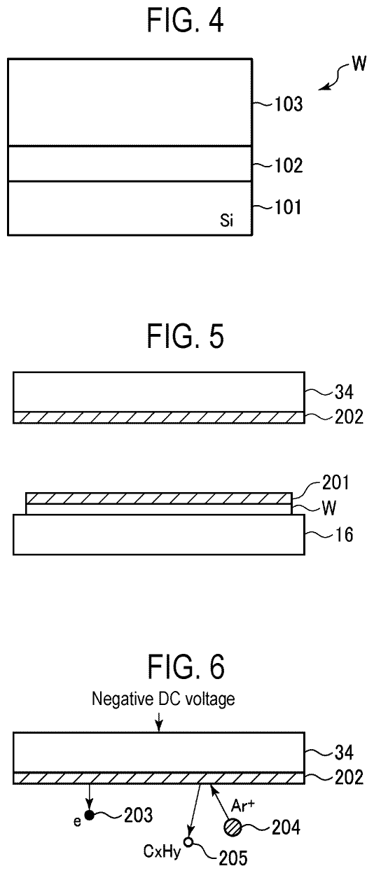

In step ST3, while supplying a process gas containing a carbon-containing gas into the depressurized processing container 10, a carbon film is formed on the substrate by generating plasma through application of radio frequency power for plasma generation from the first radio frequency power supply 88 to the substrate placement stage 16 serving as the lower electrode. As a specific example, as illustrated in FIG. 4, a carbon film 103 is formed on the base film 102 of the substrate W in FIG. 3. During step ST3, it is desirable to perform a step of applying a bias from the second radio frequency power supply 91 to the substrate placement stage 16. By applying the bias from the second radio frequency power supply 91 to the substrate placement stage 16, stress of the carbon film can be reduced.

The carbon-containing gas used to generate plasma may be, for example, acetylene (C₂H₂) gas. In addition to the acetylene (C₂H₂) gas, methane (CH₄) gas, ethylene (C₂H₄) gas, ethane (C₂H₆) gas, propylene (C₃H₆) gas, propyne (C₃H₄) gas, propane (C₃H₈) gas, butane (C₄H₁₀) gas, butylene (C₄H₈) gas, butadiene (C₄H₆) gas, or phenylacetylene (C₈H₆) gas can be used as the carbon-containing gas. A mixed gas containing a plurality of gases selected from these gases may also be used. In addition to the carbon-containing gas, a noble gas may also be added. As the noble gas, Ar gas or He gas can be used.

In step ST4, plasma processing is performed by applying a negative DC voltage from the DC power supply 94 to the upper electrode 34, which is a counter electrode facing the substrate placement stage 16, along with application of the radio frequency power from the radio frequency power supply 88 to the substrate placement stage 16 serving as the lower electrode. During plasma processing in step ST4, a noble gas such as Ar gas is introduced into the processing container 10 to generate plasma. In this case, hydrogen gas (H₂ gas) may be added together with the noble gas. The following model can be considered for an effect of adding the H₂ gas.

First, the case in which plasma processing is performed using only the noble gas such as the Ar gas can be considered. Carbon atoms sputtered from the upper electrode 34 serving as the counter electrode facing the substrate placement stage 16 by the noble gas are supplied to the substrate without bonding with other atoms. In this case, depending on an ion energy of the carbon atoms, the carbon atoms are implanted into a substrate surface to a depth of a few atomic layers. After being implanted, the carbon atoms reconstruct a carbon bond in the vicinity of the carbon atoms, which causes a structural change in the film. However, the state of the film before the carbon atoms are implemented is configured to be structurally stable, and when the carbon atoms are suddenly implanted, dangling bonds of the carbon atoms cannot all be reconstructed to form stable bonds with the nearby carbon atoms, and the carbon atoms may remain in an unstable structure at the implanted position. In that case, the unstable dangling bonds may cause local film stress or become a reaction site with moisture in an atmosphere when the film is exposed to the atmosphere after film formation. On the other hand, when hydrogen is added to the noble gas, the carbon atoms sputtered from the upper electrode 34, which serves as the counter electrode facing the substrate placement stage, bond with dissociated hydrogen to become CHₓ. In this case, since some of the dangling bonds are terminated by hydrogen before penetrating the substrate, the film is easily reconstructed when the dangling bonds are implanted into the substrate surface, and as a result, film stress may be reduced.

A similar phenomenon may occur in normal plasma CVD film formation. For example, when a film is formed by plasma CVD using a gas such as CH₄ as the carbon-containing gas, hydrogen may dissociate from a CH₄ molecule through various collision processes, and CHₓ may be supplied to the substrate. However, the difference between the embodiment and a conventional method is considered to exist in terms of the following points. That is, it is considered that, in the embodiment, the distance between the electrodes is an order of a few cm, and a pressure range is a low pressure zone of a few tens of mTorr, so that an appropriate amount of hydrogen adheres to the carbon atoms sputtered from the counter electrode, and, at this time, more carbon-rich CHₓ is generated than a conventional case where gases are dissociated in plasma starting from a carbon-containing gas containing a large amount of hydrogen, thereby effectively relieving film stress when the carbon-rich CHₓ is implanted into the substrate.

In step ST4, stress of the carbon film formed on the substrate W can be relieved by applying a DC voltage to the upper electrode 34 serving as the counter electrode.

Hereinafter, a detailed description will be given.

The carbon film formed by converting the carbon-containing gas into plasma is an amorphous carbon film, which is composed of diamond-like carbon with a large sp³ bond ratio, and has a high density and high etching resistance. For this reason, the carbon film is suitable as a next-generation hard mask.

On the other hand, the hard mask is required to have low film stress in addition to the high density. That is, in general, even for films with the same stress, a warpage of the substrate due to the film stress increases as the thickness of the film increases. When the thickness of the film required for the hard mask is 1 μm or more, the warpage may exceed an allowable warpage amount (e.g., 200 μm) of the substrate for performing transfer or lithography, making it difficult to perform post-processing after film formation. However, although the conventional carbon film formed by plasma of the carbon-containing gas has a high density and high etching resistance, it has high film stress as film density increases. In other words, there is a trade-off relationship between film density and film stress. As the film density becomes higher, the film stress is increased, making it difficult to obtain the carbon film with a high density and low stress.

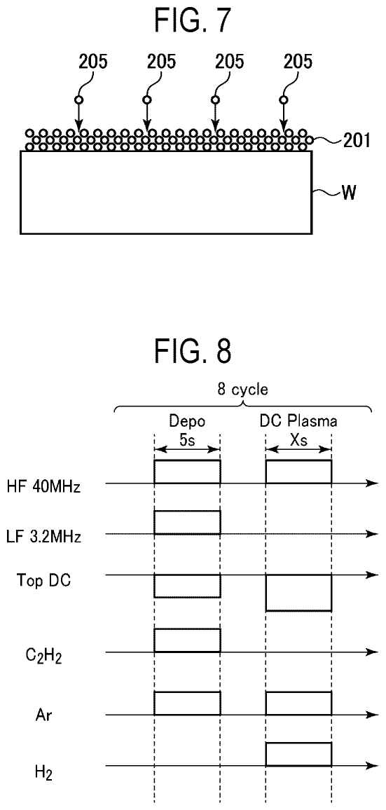

In the embodiment, when the carbon film is formed through plasma CVD by converting the carbon-containing gas into plasma in step ST3, as illustrated in FIG. 5, a carbon film 201 is formed on the substrate W, and at the same time, a carbon film (CₓH_{y} film) 202 is deposited on the surface of the upper electrode 34 serving as the counter electrode facing the substrate W. The amount of film formation depends on a potential state of the surface but may be considered to be approximately the same as the amount of film formation on the substrate. For example, when the carbon film 201 is formed on the substrate W to a thickness of 5 nm, the carbon film 202 deposited on the upper electrode 34 is also approximately 5 nm thick. In this state, as illustrated in FIG. 6, when a negative DC voltage is applied to the upper electrode 34 in step ST4, secondary electrons 203 are emitted from the upper electrode 34, and ions (e.g., argon ion) 204 in plasma are attracted to the upper electrode 34 and sputter the carbon film 202 on the surface thereof, thereby emitting carbon particles (CₓH_{y}) 205. As illustrated in FIG. 7, it is considered that the stress of the carbon film 201 is alleviated by implanting the carbon particles 205 having higher energy into the carbon film 201 formed on the substrate W.

Experiments verifying this will be described below. The electrode plate 36 of the upper electrode 34 was made of silicon, a film was formed by applying a DC voltage to the upper electrode 34 while generating radio frequency plasma, and a relationship between a film formation time and film stress was investigated. Here, as illustrated in FIG. 8, carbon film formation (hereinafter also referred to as deposition) in step ST3 and plasma processing through application of the DC voltage (hereinafter also referred to as DC plasma) in step ST4 were repeated 8 times in a state in which a deposition time was set to 5 sec and a DC plasma time varied. Conditions for deposition were pressure: 20 mTorr, 40 MHz radio frequency power (HF) power: 400 W, 3.2 MHz radio frequency power (LF) power: 500 W, direct current voltage (DC): −75 V, carbon-containing gas: C₂H₂ gas, and flow rate of C₂H₂ gas/Ar gas: 50/100 sccm. Conditions for DC plasma were pressure: 100 mTorr, HF power: 400 W, DC: −900 V, and flow rate of H₂ gas/Ar gas: 200/500 sccm.

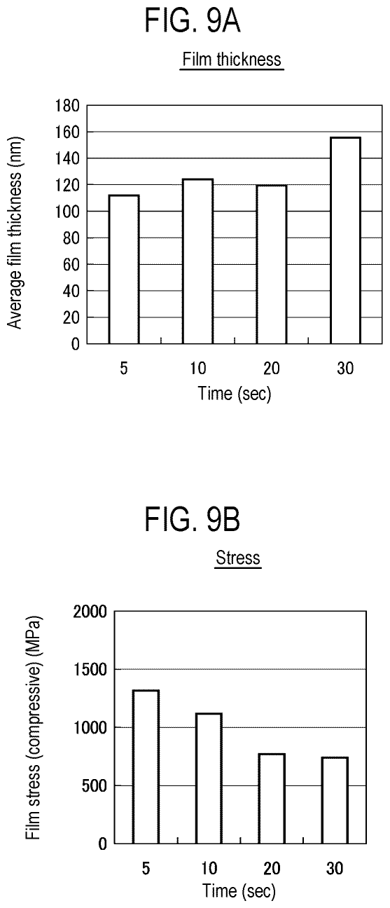

The results are illustrated in FIGS. 9A and 9B. FIG. 9A illustrates a relationship between a DC plasma time and a carbon film thickness, and FIG. 9B illustrates a relationship between the DC plasma time and film stress (compressive). As illustrated in FIG. 9A, the film thickness tends to increase as the DC plasma time increases. In addition, as illustrated in FIG. 9B, a film sample up to a DC plasma time of 20 seconds showed a large stress reduction effect, but when the DC plasma time was 30 seconds, the stress reduction effect was saturated. In addition, in the sample with a DC voltage application time of up to 20 seconds, a film formed on the substrate was a carbon film, whereas silicon was detected in the film of the sample with an application time of 30 seconds.

This illustrates that the carbon film deposited on the upper electrode 34 (electrode plate 36) serving as the counter electrode is sputtered during plasma processing, and carbon particles are implanted into the film on the substrate, thereby reducing the film stress, and if the carbon film is completely sputtered and silicon is sputtered, no stress reduction occurs.

Further, as derived from these experimental results, if the electrode plate 36 is made of carbon, the effect of reducing the film stress is maintained even when the carbon film deposited on the electrode plate 36 is completely sputtered.

In the process of performing plasma processing by applying the DC voltage in step ST4, an absolute value of the DC voltage applied from the DC power supply 94 to the upper electrode 34 is desirably 300 V or more.

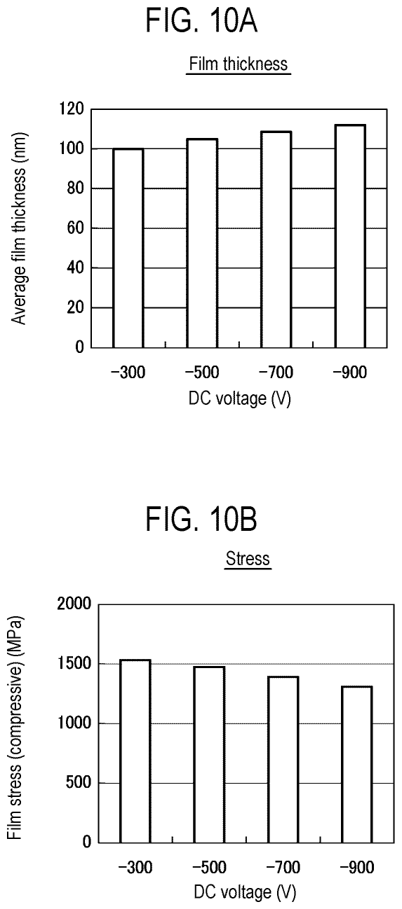

The results of an experiment for verifying this are illustrated in FIGS. 10A and 10B. Here, the conditions for deposition were the same as those in FIG. 8, and the conditions for DC plasma were the same as those in FIG. 8, except that the time was fixed at 5 sec and the DC voltage was changed from −300 to −900 V.

FIG. 10A illustrates a relationship between the DC voltage applied to the upper electrode and the carbon film thickness, and FIG. 10B illustrates a relationship between the DC voltage applied to the upper electrode and film stress. As illustrated in FIG. 10A and FIG. 10B, as the absolute value of the DC voltage increases from 300 V, the film thickness increases and the effect of reducing the film stress increases. Since it is considered that the amount of carbon sputtering from the carbon film deposited on the upper electrode increases as the absolute value of the DC voltage becomes higher, the higher the absolute value of the DC value, the better. However, depending on an apparatus, there are restrictions on specifications of a DC power supply, and in the experiments illustrated in FIG. 10A and FIG. 10B, the absolute value of the DC voltage was set to a maximum of 900 V.

As illustrated in the experimental results of FIGS. 9A and 9B, it is desirable to alternately repeat the process of forming the carbon film in step ST3 and the process of applying the DC voltage in step ST4. This allows the carbon particles to be implanted into the carbon film after a thin carbon film is formed on the substrate W, so that a stress relaxation effect due to carbon particle implantation can increase. In this case, it is desirable to set the thickness of the carbon film in one cycle to 10 nm or less.

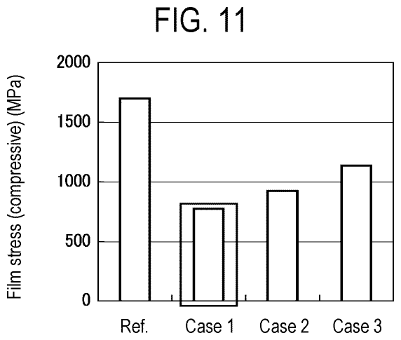

The experimental result verifying this is illustrated in FIG. 11. Here, a reference corresponds to the case in which deposition was performed for 40 seconds under the same conditions as those in FIG. 8 without performing DC plasma, and Cases 1 to 3 correspond to the cases in which DC plasma was fixed at 20 seconds and a deposition time and the number of cycles of steps ST3 and ST4 were changed. The conditions for deposition and the conditions for DC plasma were the same as those in FIG. 8 except for the time. Specifically, as shown in Table 1, in Case 1, the deposition time was 5 sec and the number of cycles was 8, in Case 2, the deposition time was 10 sec and the number of cycles was 4, and in Case 3, the deposition time was 20 sec and the number of cycles was 2. The film thickness per cycle was 10 nm in Case 1, 20 nm in Case 2, and 40 nm in Case 3.

TABLE 1

| | Deposition time | DC plasma time | Number |
|---|---|---|---|
| | (sec) | (sec) | of cycles |
| Reference | 40 | — | — |
| Case 1 | 5 | 20 | 8 |
| Case 2 | 10 | 20 | 4 |
| Case 3 | 20 | 20 | 2 |

As illustrated in FIG. 11, the film stress was lower in all of Cases 1 to 3 than in Reference, and in particular, the film stress was the lowest in Case 1. This confirmed that a sequence of performing DC plasma with a film thickness of 10 nm or less by deposition has a high effect of stress reduction.

In the process of applying the DC voltage in step ST4, the effect of stress reduction can increase as pressure at that time becomes higher, and the pressure at that time is desirably 30 m Torr (4 Pa) or more.

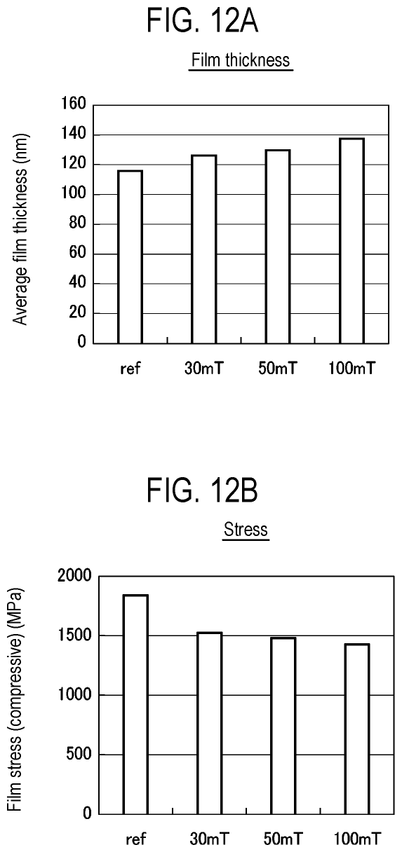

The experimental results verifying this are illustrated in FIG. 12A and FIG. 12B. Here, the pressure during DC plasma was changed between 30 and 100 mTorr, and deposition and DC plasma were repeated 8 cycles each for 5 sec. The conditions for deposition in this case were the same as those in FIG. 8, and the conditions for DC plasma were the same as those in FIG. 8 except for the time and pressure.

FIG. 12A illustrates a relationship between the DC plasma pressure and the carbon film thickness, and FIG. 12B illustrates a relationship between the DC plasma pressure and film stress (compressive). As illustrated in FIG. 12A, the film thickness tends to become thicker as the DC plasma pressure increases. In addition, as illustrated in FIG. 12B, it was confirmed that the film stress tends to decrease as the DC plasma pressure increases, and the effect of stress reduction increases as the pressure in step ST4 becomes higher.

In the process of applying the DC voltage in step ST4, the effect of film stress reduction increases as radio frequency power (HF power) from the first radio frequency power supply 88 for plasma generation becomes higher. In this case, the power is desirably 200 W or more.

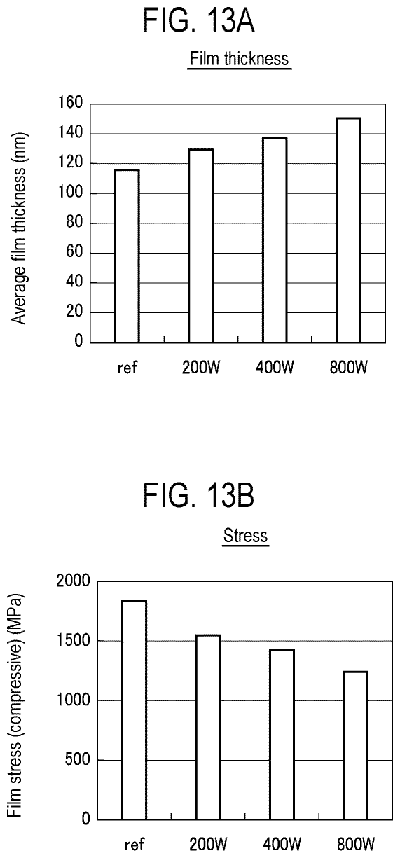

The results of experiments verifying this are illustrated in FIGS. 13A and 13B. Here, the HF power during DC plasma was changed to 200 W, 400 W, and 800 W, and deposition and DC plasma were repeated 8 cycles each for 5 sec. The conditions for deposition in this case were the same as those in FIG. 8, and the conditions for DC plasma were the same as those in FIG. 8 except for the time and the HF power.

FIG. 13A illustrates a relationship between the HF power of DC plasma and the carbon film thickness, and FIG. 13B illustrates a relationship between the HF power of DC plasma and the film stress (compressive). As illustrated in FIG. 13A, the film thickness tends to become thicker as the HF power of the DC plasma increases. Further, as illustrated in FIG. 13B, it was confirmed that the film stress tends to decrease as the HF power of the DC plasma increases, and the effect of stress reduction increases as the HF power in step ST4 increases.

In the film forming apparatus 100 in FIG. 1, while the radio frequency power of a lower frequency (e.g., 3.2 MHZ) than the radio frequency power for plasma generation is applied from the second radio frequency power supply 91 for bias application, a DC bias may be applied.

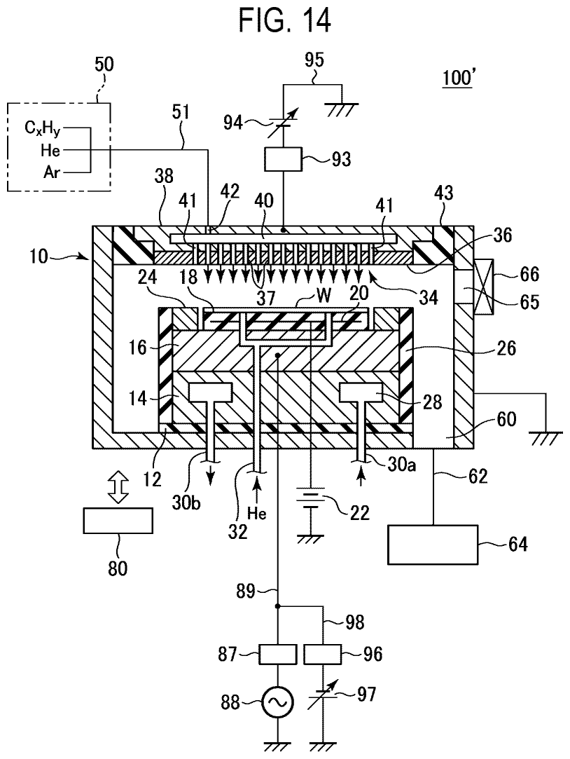

FIG. 14 is a cross-sectional view illustrating an example of a film forming apparatus that applies a DC bias. In a film forming apparatus 100′ of FIG. 14, a DC power supply 97 for applying a bias is electrically connected to the substrate placement stage 16 serving as the lower electrode. A feeder 98 from the DC power supply 97 for applying a bias is connected to the feeder 89 of the first radio frequency power supply 88, and a DC voltage from the DC power supply 97 for applying the bias is applied to the substrate placement stage 16 via the feeder 98 and the feeder 89. A low-pass filter 96 is disposed on the feeder 98 connected to the DC power supply 97 so that radio frequency power from the first radio frequency power supply 88 is not supplied to the DC power supply 97. A negative electrode of the DC power supply 97 is connected to the substrate placement stage 16.

The other components of the film forming apparatus 100′ of FIG. 14 are the same as those of the film forming apparatus 100 of FIG. 1, so that the same reference numerals are used and a description thereof is omitted.

### Second Embodiment

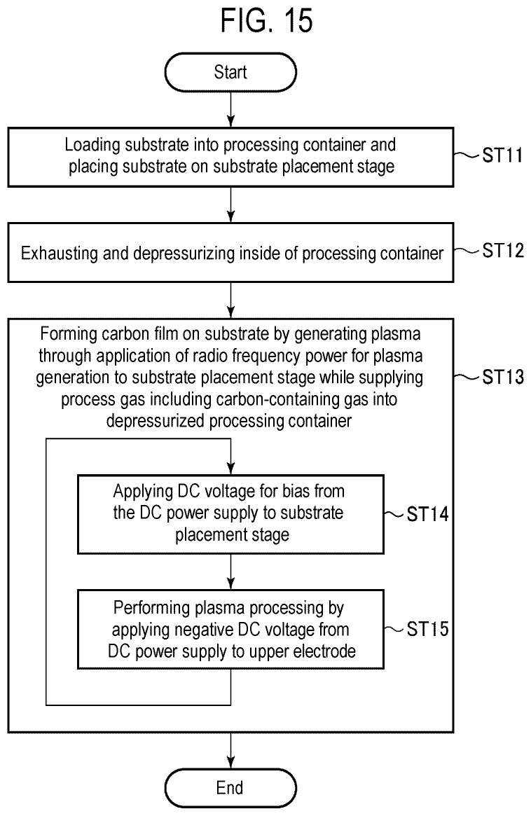

Next, a film forming method according to a second embodiment will be described. FIG. 15 is a flowchart illustrating an exemplary flow of the film forming method according to the second embodiment. This embodiment can be implemented using the film forming apparatus 100′ illustrated in FIG. 14 described above.

As shown in FIG. 15, in this embodiment, steps ST11 to ST15 are performed.

In step ST11, the substrate W is loaded into the processing container 10 and placed on the substrate placement stage 16. Step ST11 is performed in the same manner as step ST1 in the first embodiment.

In step ST12, the inside of the processing container 10 is exhausted and depressurized. Step ST12 is performed in the same manner as step ST2 in the first embodiment.

In step ST13, while supplying a process gas containing a carbon-containing gas into the depressurized processing container 10, a carbon film is formed on the substrate by generating plasma through application of radio frequency power for plasma generation from the first radio frequency power supply 88 to the substrate placement stage 16 serving as the lower electrode. Step ST13 is performed in the same manner as step ST3 in the first embodiment.

Steps ST14 and ST15 are performed alternately during a period in which the carbon film is formed in step ST13. That is, steps ST14 and ST15 are performed alternately while the radio frequency power is applied from the radio frequency power supply 88 to the substrate placement stage 16 and the gas containing the carbon-containing gas is continuously supplied into the processing container 10 in step ST13.

In step ST14, a DC voltage for a bias is applied from the DC power supply 97 to the substrate placement stage 16. This DC bias has an effect of reducing the stress of the formed carbon film, similar to the radio frequency bias in the first embodiment. The DC bias voltage applied to the substrate placement stage 16 is a negative DC voltage and is desirably 500 V to 3 kV. Step ST14 may be performed by applying a radio frequency bias from the second radio frequency power supply 91 to the substrate placement stage 16 using the film forming apparatus 100 of FIG. 1.

In step ST15, similar to step ST4 of the first embodiment, plasma processing is performed by applying a negative DC voltage from the DC power supply 94 to the upper electrode 34 serving as the counter electrode.

In this way, the stress of the formed carbon film can be reduced by applying the DC bias to the substrate placement stage 16 in step ST14, and film stress can be reduced through implantation of carbon particles into the formed carbon film by applying the DC voltage to the upper electrode 34 in step ST15. During the film formation of the carbon film in step ST13, the carbon film with low stress can be obtained by alternately performing stress reduction of the formed carbon film itself in step ST14 and stress relaxation of the carbon film after film formation in step ST15.

Since steps ST14 and ST15 can be performed at high speed by switching the application of the DC voltage to the substrate placement stage 16 serving as the lower electrode and to the upper electrode 34, stress relaxation of the carbon film in step ST15 can be enhanced.

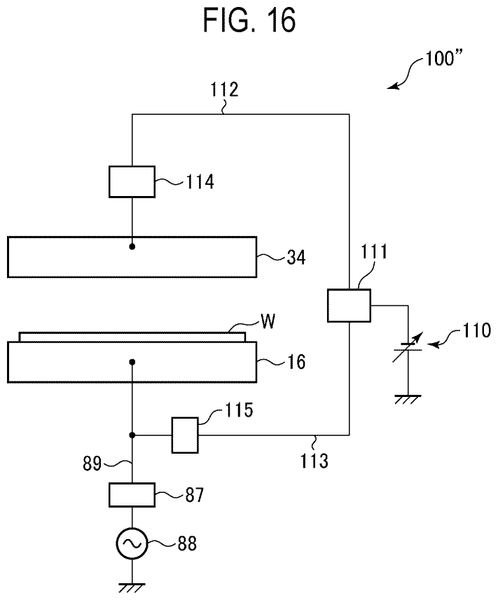

In this embodiment, steps ST14 and ST15 can be performed by switching the application of the DC voltage to the substrate placement stage 16 serving as the lower electrode and to the upper electrode 34, and therefore, a single DC power supply may be used to switch application of the DC voltage to the substrate placement stage 16 and the upper electrode 34. An example of such a film forming apparatus is shown in FIG. 16. FIG. 16 is a schematic diagram schematically illustrating main parts of such a film forming apparatus. A film forming apparatus 100″ of this example has one DC power supply 110, and a negative electrode of the DC power supply 110 is connected to a switch 111. The switch 111 is connected to the upper electrode 34 by a feeder 112 and to the substrate placement stage 16 serving as the lower electrode by a feeder 113. Low-pass filters 114 and 115 are disposed on the feeders 112 and 113, respectively, so that radio frequency power from the first radio frequency power supply 88 is not supplied to the DC power supply 110.

With this configuration, steps ST14 and ST15 can be performed by switching the application of the DC voltage from the single DC power supply 110 to the substrate placement stage 16 and the upper electrode 34 through switching of the switch 111, and a film forming apparatus of a simpler structure can be achieved.

### Other Applications

While certain embodiments have been described, these embodiments have been presented by way of example only, and are not intended to limit the scope of the disclosure. The embodiments described herein may be omitted, replaced, or changed into a variety of other forms without departing from the spirit of the disclosure.

For example, the film forming apparatus of the above embodiment is merely illustrative, and apparatuses of various configurations can be used. In addition, while the semiconductor wafer is used as the substrate, the substrate is not limited to the semiconductor wafer and may be a flat panel display (FPD) substrate, which is a representative of a substrate for a liquid crystal display (LCD), or other substrates such as a ceramic substrate.

### EXPLANATION OF REFERENCE NUMERALS

10: processing container, 16: substrate placement stage (lower electrode), 34: upper electrode, 50: gas supply, 64: exhauster, 80: controller, 88: first radio frequency power supply, 91: second radio frequency power supply, 94, 97, 110: DC power supply, 100, 100′, 100″: film forming apparatus, 101: Si substrate, 102: base film, 103: carbon film, 111: switch, 201: carbon film on substrate, 202: carbon film (CₓH_{y} film) deposited on upper electrode, 203: secondary electron, 204: ion, 205: carbon particle (CₓH_{y}), W: substrate

1. A film forming method, comprising:
placing a substrate on a substrate placement stage provided inside a processing container;
exhausting and depressurizing an inside of the processing container;
forming a carbon film on the substrate by generating plasma through application of radio frequency power for plasma generation to the substrate placement stage while supplying a process gas including a carbon-containing gas into the depressurized processing container; and
performing plasma processing by applying a negative direct current voltage to a counter electrode facing the substrate placement stage, along with application of the radio frequency power for plasma generation to the substrate placement stage.

2. The film forming method of claim 1, further comprising applying radio frequency power or a direct current voltage for a bias to the substrate placement stage in a period in which the forming the carbon film is performed.

3. The film forming method of claim 1, wherein the performing the plasma processing by applying the negative direct current voltage to the counter electrode is performed in a state in which the process gas including the carbon-containing gas is not supplied.

4. The film forming method of claim 1, wherein the forming the carbon film and the performing the plasma processing by applying the negative direct current voltage to the counter electrode are alternately repeated.

5. The film forming method of claim 4, wherein the forming the carbon film includes forming the carbon film to a thickness of 10 nm or less in one cycle.

6. The film forming method of claim 4, wherein applying the radio frequency power or a direct current voltage for a bias to the substrate placement stage is not performed in a period in which the performing the plasma processing by applying the negative direct current voltage to the counter electrode is performed.

7. The film forming method of claim 4, wherein the performing the plasma processing by applying the negative direct current voltage to the counter electrode is performed under a pressure of 4 Pa or higher.

8. The film forming method of claim 2, wherein an absolute value of the direct current voltage applied to the counter electrode when the performing the plasma processing by applying the negative direct current voltage to the counter electrode is performed is 300 V or more.

9. The film forming method of any one of claim 1, wherein the radio frequency power for plasma generation applied when the performing the plasma processing by applying the negative direct current voltage to the counter electrode is performed is 200 W or more.

10. The film forming method of claim 1, further comprising applying a direct current voltage for a bias to the substrate placement stage,
wherein the applying the direct current voltage for the bias to the substrate placement stage and the performing the plasma processing by applying the negative direct current voltage to the counter electrode are alternately repeated in a period in which the forming the carbon film is performed.

11. The film forming method of claim 10, wherein the performing the plasma processing by applying the negative direct current voltage to the counter electrode and the applying the direct current voltage for the bias to the substrate placement stage are performed by switching a direct current voltage from one direct current power supply.

12. A film forming apparatus, comprising:
a processing container configured to accommodate a substrate;
a substrate placement stage configured to place the substrate inside the processing container;
a counter electrode provided to face the substrate placement stage;
a gas supply configured to supply a process gas into the processing container;
an exhauster configured to exhaust and depressurize an inside of the processing container;
a radio frequency power supply configured to supply radio frequency power for plasma generation to the substrate placement stage;
a direct current power supply configured to apply a negative voltage to the counter electrode; and
a controller,
wherein the controller is configured to control the gas supply, the exhauster, the radio frequency power supply, and the direct current power supply so as to execute:
controlling the exhauster such that the inside of the processing container is depressurized to a desired pressure in a state in which the substrate is placed on the substrate placement stage;
forming a carbon film on the substrate by generating plasma through application of the radio frequency power for plasma generation to the substrate placement stage while supplying the process gas including a carbon-containing gas into the depressurized processing container; and
performing plasma processing by applying a negative direct current voltage to a counter electrode facing the substrate placement stage, along with application of the radio frequency power for plasma generation to the substrate placement stage.

13. The film forming apparatus of claim 12, further comprising a bias power supply configured to apply radio frequency power or a direct current voltage for a bias to the substrate placement stage,
wherein the controller performs control such that applying the radio frequency power or the direct current voltage for the bias to the substrate placement stage is executed in a period in which the forming the carbon film is performed.

14. The film forming apparatus of claim 12, wherein the controller performs control such that the forming the carbon film and the performing the plasma processing by applying the negative direct current voltage to the counter electrode are alternately repeated.

15. The film forming apparatus of claim 14, wherein the controller performs control such that the performing the plasma processing by applying the negative direct current voltage to the counter electrode is performed in a state in which the process gas including the carbon-containing gas is not supplied.

16. The film forming apparatus of claim 14, wherein the controller performs control such that applying the radio frequency power or a direct current voltage for a bias to the substrate placement stage is not performed in a period in which the applying the direct current voltage to the counter electrode is performed.

17. The film forming apparatus of claim 12, further comprising a bias power supply configured to apply a direct current voltage for a bias to the substrate placement stage,
wherein the controller performs control such that applying the direct current voltage for the bias to the substrate placement stage is performed, and
wherein the controller performs control such that the performing the plasma processing by applying the negative direct current voltage to the counter electrode and the applying the direct current voltage for the bias to the substrate placement stage are alternately repeated in a period in which the forming the carbon film is performed.

18. The film forming apparatus of claim 17, wherein the direct current power supply and the bias power supply are a common direct current power supply, and
wherein the controller performs control such that the performing the plasma processing by applying the negative direct current voltage to the counter electrode and the applying the direct current voltage for the bias to the substrate placement stage are performed by switching a direct current voltage from the common direct current power supply.
